(19) United States
(12) Patent Application Publication
(10) Pub. No.: US 2006/0209107 A1
(43) Pub. Date: Sep. 21, 2006

(54) Liquid droplet spraying apparatus, method of forming a pixel pattern using the same and display substrate having the pixel pattern

(76) Inventors: Seong-Gyu Kwon, Suwon-si (KR); Byoung-Joo Kim, Anyang-si (KR); Jang-Sub Kim, Suwon-sin (KR); Yoon-Ho Kang, Yongin-si (KR)

Correspondence Address: CANTOR COLBURN, LLP, 55 GRIFFIN ROAD SOUTH, BLOOMFIELD, CT, 06002, US

(21) Appl. No.: 11/367,783

(22) Filed: Mar. 3, 2006

(30) Foreign Application Priority Data
Mar. 18, 2005 (KR) 2005-22503

(51) Int. Cl. B41J 29/38

(52) U.S. Cl. 347/9

(57) ABSTRACT

A liquid droplet spraying apparatus sprays a liquid droplet onto pixel regions arranged in a matrix shape. The liquid droplet spraying apparatus includes a first spraying section and a second spraying section. The first spraying section sprays a first liquid droplet onto a pixel region, the first spraying section moving along a first path. The second spraying section sprays a second liquid droplet onto the pixel region, the second spraying section moving along a second path. A liquid material is dropped multiple times by small amount, such that an accurate amount of the liquid material may be dropped. Advantageously, by dropping the liquid material by both of the first and second spraying sections, a time for dropping the liquid material may be reduced.

This application claims priority to Korean Patent Application No. 2005-22503 filed on Mar. 18, 2005, and all the benefits accruing therefrom under 35 U.S.C. §119, the contents of which are herein incorporated by reference in its entirety.

### BACKGROUND OF THE INVENTION

1. Field of the Invention

The present invention relates to a liquid droplet spraying apparatus, a method of forming a pixel pattern using the liquid droplet spraying apparatus, and a display substrate having the pixel pattern. More particularly, the present invention relates to a liquid droplet spraying apparatus that sprays liquid droplet by an inkjet method, a method of forming a pixel pattern using the liquid droplet spraying apparatus, and a display substrate having the pixel pattern.

2. Description of the Related Art

A display apparatus converts data processed by an information processing apparatus into images. Examples of the display apparatus include a liquid crystal display (LCD) apparatus, an organic light emitting display (OLED) apparatus, a plasma display panel (PDP) and the like. The above-mentioned display apparatus has a lighter weight and a smaller volume than that of a cathode ray tube (CRT) display apparatus.

Each of the above-mentioned display apparatuses includes a plurality of pixels. For example, a pixel of the LCD apparatus includes a thin film transistor (TFT), a gate line, a data line, a pixel electrode, a black matrix, a color filter and a common electrode. A pixel of the OLED apparatus includes an anode electrode, an electron-injection layer, a hole-injection layer, a cathode electrode and an organic layer.

In order to manufacture the above-mentioned display apparatus, numerous processes, for example, a depositing process, a photoresist patterning process, an etching process, a cleaning process and the like. are required. Therefore, manufacturing the above-mentioned display apparatuses requires a large amount of time which results in lower productivity.

### SUMMARY OF THE INVENTION

The present invention provides a liquid droplet spraying apparatus capable of reducing a number of processes.

The present invention also provides a method of forming a pixel pattern by using the above liquid droplet spraying apparatus.

The present invention also provides a display substrate having a pixel pattern formed by the above liquid droplet spraying apparatus.

In an exemplary embodiment, a liquid droplet spraying apparatus sprays a liquid droplet onto pixel regions arranged in a matrix shape. The liquid droplet spraying apparatus includes a first spraying section and a second spraying section. The first spraying section sprays a first liquid droplet onto a pixel region, as the first spraying section moving along a first path. The second spraying section sprays a second liquid droplet onto the pixel region, as the second spraying section moves along a second path.

In another exemplary embodiment, a method of forming a pixel pattern is provided. A blocking pattern having a plurality of openings arranged in a matrix shape is formed on a base substrate. The openings correspond to pixel regions. A first droplet is dropped onto a pixel region along a first path. A second droplet is dropped onto the pixel region along a second path. The first and second droplets make contact with each other on the pixel region. The first and second droplets dropped onto the pixel region are dried to form a pixel pattern.

In another exemplary embodiment, a display substrate is provided, the display substrate including a base substrate, a blocking pattern and a plurality of pixel patterns. The blocking pattern is formed on the base substrate. The blocking pattern has a plurality of openings arranged in a matrix shape. The pixel patterns are formed at an opening. A pixel pattern has a first portion having a first profile and a second portion having a second profile that is different form the first profile. The first portion and the second portion contact each other.

In another exemplary embodiment, a liquid material is dropped multiple times by a small amount, such that an accurate amount of the liquid material may be dropped. Advantageously, by dropping the liquid material by both of the first and second spraying sections, a time for dropping the liquid material may be reduced.

### BRIEF DESCRIPTION OF THE DRAWINGS

The above and other features and advantages of the present invention will become more apparent by describing in detailed exemplary embodiments thereof with reference to the accompanying drawings, in which:

FIG. 1 is a schematic plan view illustrating an exemplary embodiment of a liquid droplet spraying apparatus according to the present invention;

FIG. 2 is a plan view illustrating an exemplary embodiment of a position of first and second liquid droplets sprayed by the liquid droplet spraying apparatus in FIG. 1;

FIG. 3 is a schematic side view illustrating an exemplary embodiment of a transferring section of the liquid droplet spraying apparatus in FIG. 1;

FIG. 4 is a schematic side view illustrating another exemplary embodiment of a transferring section of the liquid droplet spraying apparatus in FIG. 1;

FIG. 5 is a plan view illustrating another exemplary embodiment of a liquid droplet spraying apparatus according to the present invention;

FIG. 6 is a plan view illustrating an exemplary embodiment of a substrate according to the present invention;

FIG. 7 is a cross-sectional view taken along line I-I′ in FIG. 6;

FIG. 8 is a plan view illustrating an exemplary embodiment of first liquid droplet and second liquid droplets after being sprayed onto pixel regions;

FIG. 9 is a cross-sectional view taken along line II-II′ in FIG. 8;

FIG. 10 is a cross-sectional view illustrating an exemplary embodiment of a fluid material that is dried in FIG. 9;

FIG. 11 is a plan view illustrating an exemplary embodiment of a display substrate according to the present invention;

FIG. 12 is a plan view illustrating another exemplary embodiment of a display substrate according to the present invention; and

FIG. 13 is a cross-sectional view illustrating another exemplary embodiment of a display substrate according to the present invention.

### DETAILED DESCRIPTION OF THE INVENTION

It should be understood that the exemplary embodiments of the present invention described below may be varied modified in many different ways without departing from the inventive principles disclosed herein, and the scope of the present invention is therefore not limited to these particular flowing embodiments. Rather, these embodiments are provided so that this disclosure will be thorough and complete, and will fully convey the concept of the invention to those skilled in the art by way of example and not of limitation. In the drawings, the size and relative sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the embodiments of the present invention will be described in detail with reference to the accompanied drawings.

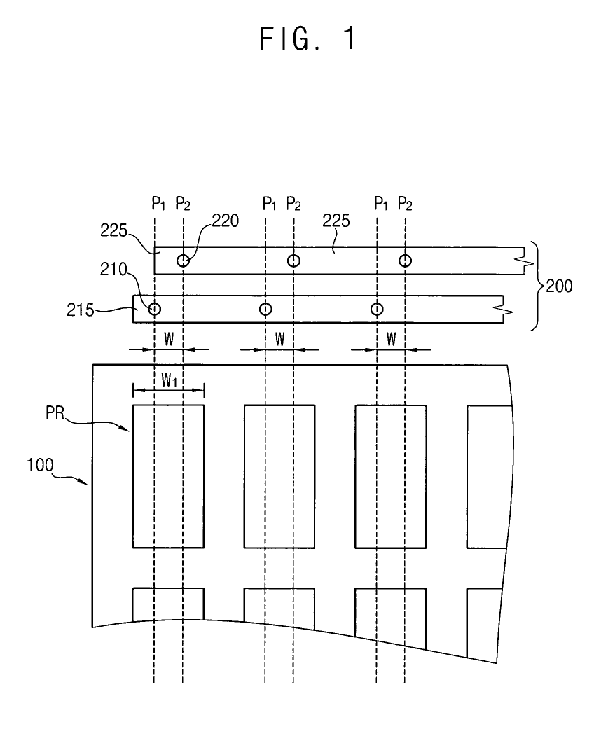

FIG. 1 is a schematic plan view illustrating an exemplary embodiment a liquid droplet spraying apparatus according to the present invention.

Referring to FIG. 1, a liquid droplet spraying apparatus 200 sprays liquid droplet onto a base substrate 100.

The base substrate 100 includes a plurality of pixel regions PR arranged in a matrix shape. Each of the pixel regions PR includes pixel patterns. For example, when a resolution of a display device is about 1024×768, then 1024×768×3 number of pixel regions PR may be formed on the base substrate 100.

The liquid droplet spraying apparatus 200 includes a first spraying section 210 and a second spraying section 220. The first spraying section 210 sprays a first liquid droplet onto the pixel region PR, and the second spraying section 220 sprays a second liquid droplet onto the pixel region PR. In exemplary embodiments, the pixel region PR may already have the first liquid droplet previously sprayed by the first spraying section 210 when the second liquid droplet is sprayed onto the pixel region PR by the second spraying section 220.

The first spraying section 210 may spray the first liquid droplet along a first path P1 that passes through a pixel region PR, and the second spraying section 220 may spray the second liquid droplet along a second path P2 that also passes through the pixel region PR.

The first and second paths P1 and P2 may be substantially in parallel with each other, and may be spaced apart from each other by a distance W. Referring to FIG. 1, the first and second paths P1 and P2 are shown substantially parallel and passing through the approximate centers of the first and second spraying sections 210 and 220. A width of the pixel region PR may be defined a W1. In exemplary embodiments, the distance W between the first and second paths P1 and P2 may be smaller than a width W1 of the pixel region PR.

The first and second liquid droplets sprayed by the first and second spraying sections 210 and 220 along first and second paths P1 and P2, respectively, are disposed on the pixel region PR. In exemplary embodiments, the first and second liquid droplets may be arranged in parallel with each other.

Referring to FIG. 1, the first spraying section 210 is disposed over a first body 215. The first body 215 may have, a rectangular plate shape or any shape suitable for the purpose described herein. In exemplary embodiments, the first spraying section 210 may correspond to a through hole formed at the first body 215.

The second spraying section 220 is disposed over a second body 225. The second body 225 may be a rectangular plate shape or any shape suitable for the purpose described herein. In exemplary embodiments, the second spraying section 220 may corresponds to a through hole formed at the second body 225.

The first and second bodies 215 and 225 may be substantially in parallel with each other. The first spraying section 210 formed at the first body 215 may be disposed over the first path P1, and the second spraying section 220 formed at the second body 225 may be disposed over the second path P2.

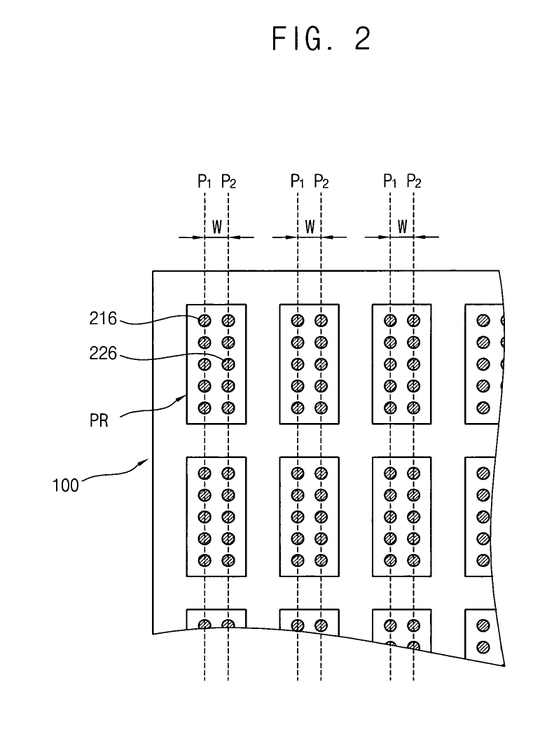

FIG. 2 is a plan view illustrating an exemplary embodiment of positioning of first and second liquid droplets sprayed by the liquid droplet spraying apparatus in FIG. 1.

The first liquid droplet is sprayed onto a first region 216 of the pixel region PR by the first spraying section 210, and the second liquid droplet is sprayed onto a second region 226 of the pixel region PR by the second spraying section 220. The first and second regions 216 and 226 may be adjacent to each other in the pixel region PR.

In exemplary embodiments, the first and second liquid droplets may be used for a red color filter, a green color filter, or a blue color filter, as well as any combination including at least one of the foregoing. White light may be converted into red light, green light and blue light by the red, green and blue color filters, respectively.

In alternative embodiments, the first and second liquid droplets may be used for a red light emitting material, a green light emitting material and a blue light emitting material.

Advantageously, when the first and second liquid droplets are simultaneously sprayed onto the pixel region PR, spraying quality is enhanced.

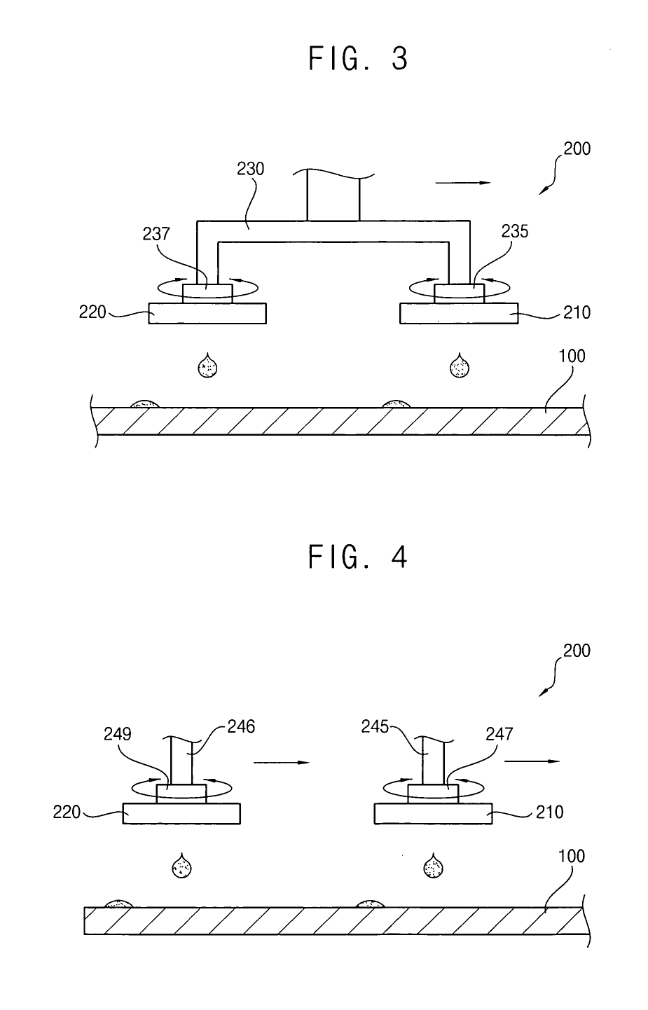

FIG. 3 is a schematic side view illustrating an exemplary embodiment of a transferring section of the liquid droplet spraying apparatus in FIG. 1.

Referring to FIG. 3, the liquid droplet spraying apparatus 200 further includes a transferring section 230. The transferring section 230 is configured to transfer the first and second spraying sections 210 and 220. The liquid droplet spraying apparatus 200 further includes a first rotating unit 235 and a second rotating unit 237. The first rotating unit 235 is formed at the transferring section 230 to rotate the first spraying section 210 as indicated by the arrow. The second rotating unit 237 is formed at the transferring section 230 to rotate the second spraying unit 220 as indicated by the arrow.

FIG. 4 is a schematic side view illustrating another exemplary embodiment of a transferring section of the liquid droplet spraying apparatus in FIG. 1.

Referring to FIG. 4, the liquid droplet spraying apparatus 200 includes a first transferring unit 245, a second transferring unit 246, a first rotating unit 247 and a second rotating unit 249. The first rotating unit 247 is combined with the first transferring unit 245, and rotates the first spraying section 210 as indicated by the arrow. The second rotating unit 249 is combined with the second transferring unit 246, and rotates the second spraying section 220 as indicated by the arrow.

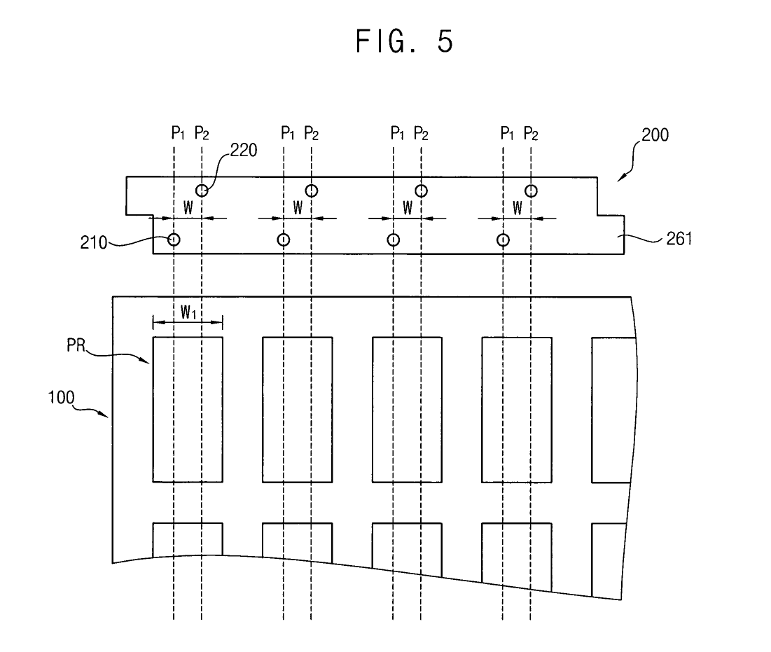

FIG. 5 is a plan view illustrating another exemplary embodiment of a liquid droplet spraying apparatus according to the present invention.

Referring to FIG. 5, a liquid droplet spraying apparatus 200 includes a body 261, a first spraying section 210 and a second spraying section 220. The first and second spraying sections 210 and 220 are formed at the body 261. The body 261 may have a plate shape or any shape suitable for the purpose described herein. In exemplary embodiments, the first and second spraying sections 210 and 220 may correspond a through hole formed at the body 261. In alternative embodiments, the first spraying section 210 may be disposed over a first path P1, and the second spraying section 220 may be disposed over a second path P2.

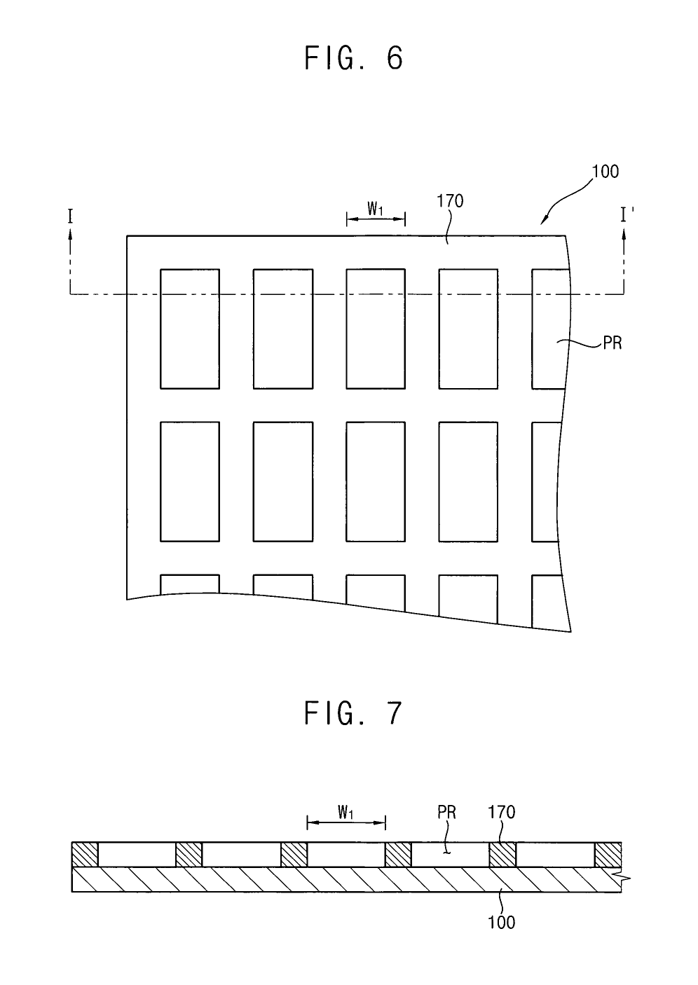

FIG. 6 is a plan view illustrating an exemplary embodiment of a base substrate according to the present invention, and FIG. 7 is a cross-sectional view taken along line I-I′ in FIG. 6.

Referring to FIGS. 6 and 7, a blocking pattern 170 is formed on a base substrate 100 in order to form a pixel pattern.

In exemplary embodiments, an optically transparent substrate such as a glass substrate may be employed as the base substrate 100. The blocking pattern 170 includes a plurality of openings arranged in a matrix shape. The openings correspond to the pixel regions PR.

In order to form the blocking pattern 170, a blocking layer (not shown) is formed on the base substrate 100, and a photoresist layer (not shown) is formed on the blocking layer. The photoresist layer is exposed and developed, and then portions of the blocking layer are removed to form the openings of the blocking pattern

A black matrix pattern of the LCD device may be formed through the above-mentioned process. The blocking pattern 170 formed by above-mentioned process may include, but is not limited to, chromium (Cr), chromium oxide (CrO₂), or the like.

In alternative embodiments, the blocking pattern 170 may be formed through a developing and baking process. To form the blocking pattern 170, a photoresist layer (not shown) is formed on the base substrate 100, and then the photoresist layer (not shown) is exposed and developed to form a photoresist pattern. The photoresist pattern is baked (or heated) to form the blocking pattern 170.

A black matrix pattern of the LCD device may be formed through the above-mentioned process. The blocking pattern 170 formed by above-mentioned process may include, but is not limited to, organic material.

When the blocking pattern 170 is formed through a developing process, the blocking pattern 170 may include a photoresist material.

The pixel regions PR are defined on the base substrate 100 by the blocking pattern 170. The pixel regions PR may be arranged in a matrix shape, as shown in FIG. 6, or in any pattern suitable for the purpose described herein.

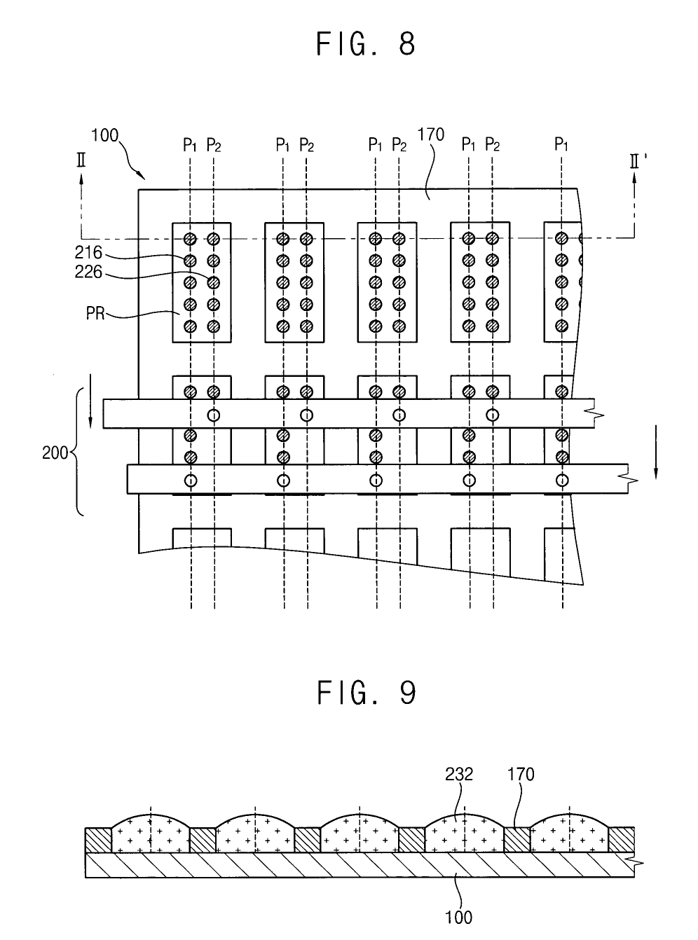

FIG. 8 is a plan view illustrating an exemplary embodiment of first liquid droplets and a second liquid droplets after being sprayed onto pixel regions by liquid droplet spraying apparatus 200. FIG. 9 is a cross-sectional view taken along line II-II′ in FIG. 8.

Referring to FIGS. 8 and 9, at least one of the first liquid droplets is dropped onto each of the pixel regions PR defined by the blocking pattern 170. In exemplary embodiments, a plurality of first liquid droplets is dropped onto each of the pixel regions PR.

A plurality of the first droplets is dropped onto the first region 216 in each of the pixel regions PR along the first path P1. In exemplary embodiments, the first liquid droplets may be used for a red color filter, a green color filter, or a blue color filter, as well as any combination including at least one of the foregoing. White light may be converted into red light, green light and blue light by the red, green and blue color filters, respectively.

In alternative embodiments, the first liquid droplets may be used for a red light emitting material, a green light emitting material and a blue light emitting material.

The first and second liquid droplets are dropped in sequence along the first and second paths P1 and P2, respectively. For example, when the first liquid is droplet is dropped onto a second pixel region PR after finishing a first pixel region PR, the second liquid droplet is dropped onto the first pixel region PR.

The second path P2 may be disposed over the pixel region PR. A plurality of the second droplets is dropped in each of the pixel regions PR along the second path P2. In exemplary embodiments, the second path P2 may be substantially in parallel with the first path P1. In other exemplary embodiments, the first and second paths P1 and P2 may be spaced apart from each other. For example, the first and second regions 216 and 226 where the first and second droplets are dropped may also be spaced part from each other.

A plurality of the second droplets is dropped onto the second region 226 in each of the pixel regions PR along the second path P2. In alternative embodiments, the second liquid droplets may be used for a red color filter, a green color filter, or a blue color filter, as well as any combination including at least one of the foregoing. White light may be converted into red light, green light and blue light by the red, green and blue color filters, respectively.

In alternative embodiments, the second liquid droplets may be used for a red light emitting material, a green light emitting material and a blued light emitting material.

Advantageously, when a liquid material is dropped multiple times in a small amount, an accurate amount of the liquid material may be dropped. Furthermore, by dropping the liquid material by both the first and second spraying sections 210 and 220, a time for dropping the liquid material may be reduced.

Referring to FIG. 9, liquid droplet 232 is shown in the pixel region PR between the blocking pattern 170. The liquid droplet 232 includes the first and second droplets dropped onto the first and second regions 216 and 226 of the pixel region. The first and second droplets ultimately contact each other in the pixel region PR between the blocking pattern 170 to form the liquid droplet 232.

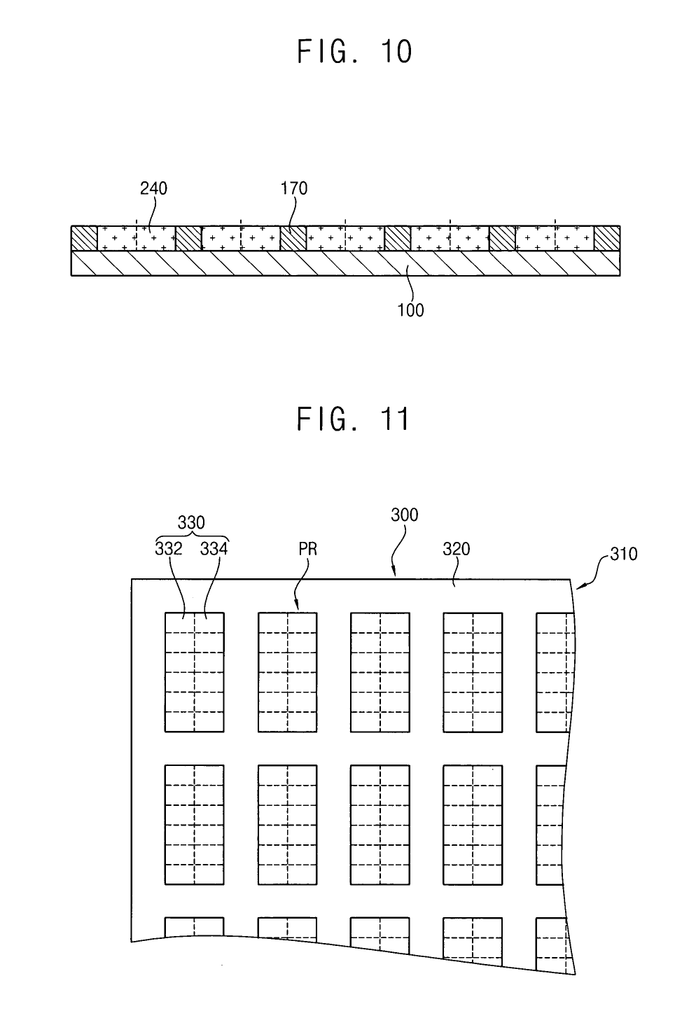

FIG. 10 is a cross-sectional view illustrating an exemplary embodiment of a fluid material that is dried in FIG. 9.

Referring to FIG. 10, after the first and second droplets of liquid material are dropped onto each of the pixel regions PR and contact each other to form liquid droplet 232, the liquid material is dried to form a pixel pattern 240. In alternative embodiments, the pixel pattern 240 may correspond to a color filter pattern including, but not limited to, a red color filter, a green color filter and a blue color filter. When the pixel pattern 240 corresponds to one of the red, green and blue color filters, the red, green and blue color filters may be alternately arranged at the pixel regions PR.

FIG. 11 is a plan view illustrating an exemplary embodiment of a display substrate according to the present invention.

Referring to FIG. 11, a display substrate 300 includes a base substrate 310, a blocking pattern 320 and a pixel pattern 330.

An optically transparent substrate may be employed as the substrate 310. The blocking pattern 320 is formed on the base substrate 310.

The blocking pattern 320 includes a plurality of openings arranged in a matrix shape.

The blocking pattern 320 may include chromium (Cr), chromium oxide (CrO₂), organic material, or the like, as well as any combination including at least one of the foregoing. In alternative embodiments, the blocking pattern 320 includes a photoresist material.

The openings of the blocking pattern 320 correspond to the pixel regions PR.

The pixel pattern 330 includes a first pixel portion 332 and a second pixel portion 334. The first pixel portion 332 is disposed in the pixel region PR. A plurality of the first pixel portions 332 is arranged in a line. In exemplary embodiments, the first pixel portions 332 may be adjacent to each other. In alternative embodiments, the first pixel portions 332 may be separated from each other.

The second pixel portion 334 is also disposed in the pixel region PR. A plurality of the second pixel portions 334 is arranged in a line. In exemplary embodiments, the second pixel portions 334 may be adjacent to each other. In alternative embodiments, the second pixel portions 334 may be separated from each other.

The first pixel portions 332 may be adjacent to each other along a first line that corresponds to the first path P1 and the second pixel portions 334 may be adjacent to each other along a second line that corresponds to the second path P2. In alternative embodiments, the first pixel portions 332 and the second pixel portions 334 may alternate with each other.

The first pixel portions 332 and the second pixel portions 334 may be adjacent to and essentially contact each other or they may be separated from each other.

When the pixel pattern 330 is formed through dropping liquid material multiple times in small amounts as described according to the present invention, each liquid droplet dropped onto one of the pixel regions PR may include different drying time, such that that a profile of each of the first and second portions 332 and 334 of the pixel pattern 330 are not identical. Where a first and a second pixel portion 332 and 334 on an opening are adjacent to each other, the liquid material dropped onto the first and second pixel portion 332 and 334 may contact each other to ultimately form the pixel pattern 330.

In exemplary embodiments, the first and second pixel portions 332 and 334 of the pixel pattern 330 may include same material. For example, the first and second pixel portions 332 and 334 may include a material used for a red color filter, a green color filter and a blue color filter. White light may be converted into red light, green light and blue light by the red, green and blue color filters, respectively.

In alternative embodiments the first and second pixel portions 332 and 334 may include a material used for a red light emitting material, a green light emitting material and a blued light emitting material.

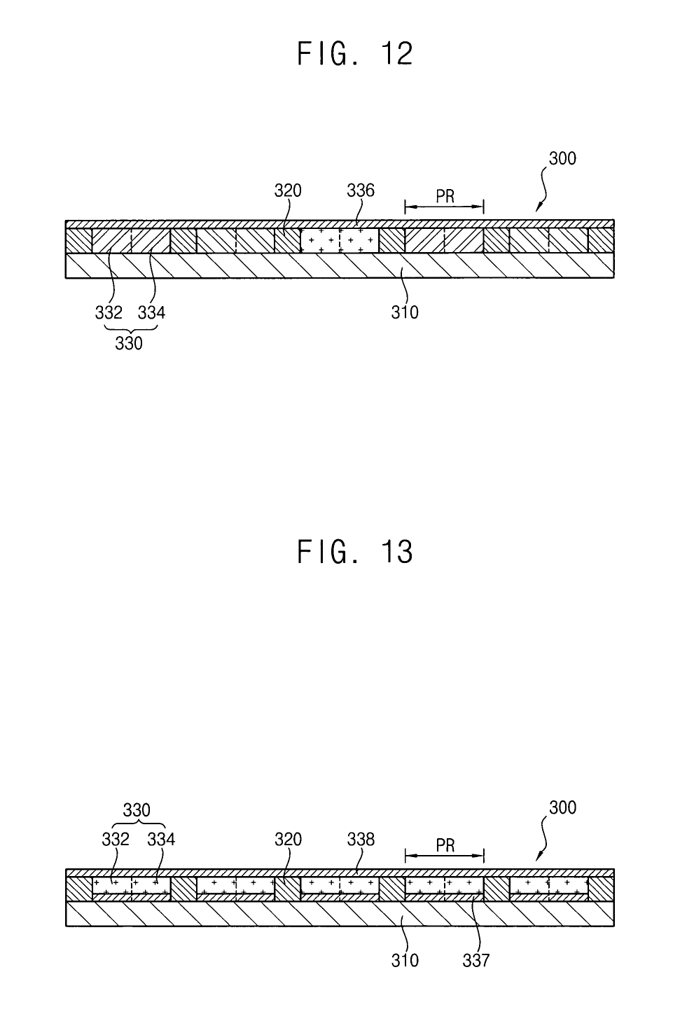

FIG. 12 is a plan view illustrating another exemplary embodiment of a display substrate according to the present invention. The display substrate of the present embodiment is same as in above-explained embodiment in FIG. 10 except for a transparent electrode. Thus, the same reference numerals will be used to refer to the same or like parts as those described in above-explained embodiment in FIG. 10 and any further explanation concerning the above elements will be omitted.

Referring to FIG. 12, when the first pixel portion 332 and the second pixel portion 334 include a material for forming a color filter substrate, a transparent electrode 336 may be formed over the base substrate 310 having the pixel pattern 330 and the blocking pattern 320 formed thereon. The transparent electrode 336 may cover the pixel pattern 330 and the blocking pattern 320.

The transparent electrode 336 may include an optically transparent and electrically conductive material. The materials of the transparent electrode 336 may include, but are not limited to, indium tin oxide (ITO), indium zinc oxide (IZO) and amorphous indium tin oxide (a-ITO).

In exemplary embodiments, the display substrate 300 having the base substrate 310, the blocking pattern 320, the pixel pattern 330 and the transparent electrode 336 may be employed as a color filter substrate of the LCD apparatus.

FIG. 13 is a cross-sectional view illustrating another exemplary embodiment of a display substrate according to the present invention. The display substrate 300 of the present embodiment is same as in above-explained embodiment in FIG. 12 except for a first electrode and a second electrode. Thus, the same reference numerals will be used to refer to the same or like parts as those described in above-explained embodiment in FIG. 12 and any further explanation concerning the above elements will be omitted.

Referring to FIG. 13, the first pixel portion 332 and the second pixel portion 334 may include a material for emitting one of red light, green light and blue light.

A first electrode 337 may be disposed between the base substrate 310 and the pixel pattern 330. A second electrode 338 may be formed on the pixel pattern 330. The pixel pattern 330 is disposed between the first and second electrodes 337 and 338.

The first electrode 337 may include an optically transparent and electrically conductive material, and the second electrode 338 may include metal material having a low work function.

In the exemplary embodiments discussed above, advantageously, an accurate amount of liquid droplet may be dropped onto the base substrate. Furthermore, a time for forming the pixel pattern may reduced.

Having described the exemplary embodiments of the present invention and its advantages, it is noted that various changes, substitutions and alterations can be made herein without departing from the spirit and scope of the invention as defined by appended claims.

What is claimed is:

1. A liquid droplet spraying apparatus spraying a liquid droplet onto pixel regions arranged in a matrix shape, the apparatus comprising:
a first spraying section that sprays a first liquid droplet onto a pixel region, when the first spraying section moves along a first path; and
a second spraying section that sprays a second liquid droplet onto the pixel region, when the second spraying section moves along a second path.

2. The liquid droplet spraying apparatus of claim 1, wherein a distance between the first and second paths are no more than a width of each of the pixel regions.

3. The liquid droplet spraying apparatus of claim 2, wherein the width of each of the pixel regions is substantially perpendicular to the first and second paths.

4. The liquid droplet spraying apparatus of claim 1, wherein the first and second paths are substantially in parallel with each other.

5. The liquid droplet spraying apparatus of claim 1, further comprising a first body and a second body, wherein the first and second spraying sections being formed over the first and second bodies, respectively.

6. The liquid droplet spraying apparatus of claim 5, further comprising a transferring unit that transfers the first and second bodies.

7. The liquid droplet spraying apparatus of claim 5, further comprising a first transferring unit that transfers the first body, and a second transferring unit that transfers the second body.

8. The liquid droplet spraying apparatus of claim 5, further comprising a first transferring unit that transfers the first body, a second transferring unit that transfers the second body, a first rotating unit combined with the first transferring unit and configured to rotate the first spraying section and a second rotating unit combined with the second transferring unit and configured to rotate the second spraying section.

9. The liquid droplet spraying apparatus of claim 1, further comprising a body, the first and second spraying sections being formed over the body.

10. A method of forming a pixel pattern, comprising:
forming a blocking pattern having a plurality of openings arranged in a matrix shape on a base substrate, the openings corresponding to pixel regions;
dropping a first droplet onto a pixel region along a first path;
dropping a second droplet onto the pixel region along a second path, so that the second droplet contacts the first droplet; and
drying the first and second droplets dropped onto the pixel region to form a pixel pattern.

11. The method of claim 10, wherein the forming a blocking pattern comprises forming a blocking layer on the substrate and forming a photoresist layer on the blocking layer.

12. The method of claim 10, wherein the dropping a first droplet and the dropping of a second droplet are performed substantially simultaneous.

13. The method of claim 10, wherein the pixel pattern corresponds to a color filter pattern.

14. The method of claim 10, wherein the pixel pattern corresponds to a light emitting pattern.

15. A display substrate comprising:
a base substrate;
a blocking pattern formed on the base substrate, the blocking pattern having a plurality of openings arranged in a matrix shape; and
a plurality of pixel patterns formed at an opening, the pixel patterns having a first portion having a first profile and a second portion having a second profile that is different from the first profile, the first and second portions contacting each other.

16. The display substrate of claim 15, wherein the pixel patterns comprise a color filter pattern.

17. The display substrate of claim 15, further comprising a transparent electrode formed over the base substrate.

18. The display substrate of claim 15, wherein the blocking pattern comprises chromium (Cr), chromium oxide (CrO₂) or an organic material.

19. The display substrate of claim 15, wherein each of the pixel patterns comprises a light emitting layer.

20. The display substrate of claim 19, wherein each of the pixel patterns further comprises a first electrode disposed between the light emitting layer and the base substrate, and a second electrode formed on the light emitting layer.

21. The display substrate of claim 15, wherein the blocking pattern comprises a photosensitive material.
